(19) United States
(12) Patent Application Publication
(10) Pub. No.: US 2014/0106264 A1
(43) Pub. Date: Apr. 17, 2014

(54) PHOTOLITHOGRAPHY MASK, PHOTOLITHOGRAPHY MASK ARRANGEMENT, AND METHOD FOR EXPOSING A WAFER

(71) Applicant: INFINEON TECHNOLOGIES AG, Neubiberg (DE)

(72) Inventors: Josef Campidell, Villach (AT); Rainer Leuschner, Regensburg (DE); Gottfried Seebacher, Weissenstein (AT)

(73) Assignee: INFINEON TECHNOLOGIES AG, Neubiberg (DE)

(21) Appl. No.: 13/834,267

(22) Filed: Mar. 15, 2013

Related U.S. Application Data
(60) Provisional application No. 61/712,280, filed on Oct. 11, 2012.

(51) Int. Cl. G03F 7/20; G03F 1/50

(52) U.S. Cl. CPC G03F 7/20; G03F 1/50
USPC 430/5; 430/322

(57) ABSTRACT

A photolithography mask according to an embodiment may include: a mask substrate, the mask substrate having a three-dimensional pattern located and dimensioned to at least partially receive an inverse three-dimensional pattern of a wafer to be exposed using the photolithography mask.

### CROSS-REFERENCE TO RELATED APPLICATION

This application claims the benefit of U.S. Provisional Application Ser. No. 61/712,280, which was filed on Oct. 11, 2012, the content of it being hereby incorporated by reference it its entirety for all purposes.

### TECHNICAL FIELD

Various embodiments relate generally to a photolithography mask, a photolithography mask arrangement, and a method for exposing a wafer.

### BACKGROUND

Photolithography may commonly be used in fabrication of semiconductor devices to create patterns on a semiconductor workpiece such as a wafer. An image of a photolithography mask may be transferred onto a light-sensitive photoresist covering at least parts of the wafer by means of exposure. In this context, it may be desirable to reduce a proximity gap between the photolithography mask and the wafer, e.g. to enhance resolution of the exposure.

### SUMMARY

A photolithography mask in accordance with an embodiment may include: a mask substrate, the mask substrate having a three-dimensional pattern located and dimensioned to at least partially receive an inverse three-dimensional pattern of a wafer to be exposed using the photolithography mask.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of various embodiments. In the following description, various embodiments are described with reference to the following drawings, in which:

FIG. 1 shows a mask aligner arrangement;

FIG. 2A shows a photolithography mask arrangement according to an embodiment;

FIG. 2B shows an enlarged view of a section of the photolithography mask arrangement of FIG. 2A.

FIG. 3 shows a photolithography mask arrangement according to another embodiment;

FIG. 4 shows a method for exposing a wafer according to another embodiment.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Photolithography may commonly be used in fabrication of semiconductor devices to create patterns on a semiconductor workpiece such as a wafer. An image of a photolithography mask (herein also referred to as photomask or, short, mask) may be transferred onto a light-sensitive photoresist covering at least parts of the wafer by means of exposure. For example in MEMS, a wafer may be required to be patterned on the front side and the back side. In this context, it may be desirable to reduce a proximity gap between the photomask and the wafer, e.g. to enhance resolution of the exposure.

Mask aligners (MA) may oftentimes be used to align the mask, in other words to exactly position the mask relative to the wafer.

Sometimes, a wafer may have a topography or surface profile that has one or more parts or areas that may protrude significantly higher than the remaining parts or areas of the wafer surface, for example a reinforcement ring. For example, a thin wafer (e.g. approximately 50 μm thickness) (e.g. thinned by grinding) may have a reinforcement ring that may be positioned on the wafer backside at an outer rim or edge of the wafer, i.e. the wafer may have protruding regions that are thicker than the remaining portion or thickness of the wafer (“high topography”). A thickness of the wafer at the protruding regions may, for example, be about 400 μm, however other values may be possible as well.

In this case of patterning the wafer back side, due to the presence of the protruding regions (e.g. reinforcement ring), the proximity gap between the mask and the wafer may be too large for achieving a good pattern resolution with a mask aligner (MA). Only a few exposure tools are capable of exposing the back side with alignment relative to the front side. Mask aligners (MA) oftentimes may have a so-called “Back Side Alignment System (BSAS)”, which may allow for a back side alignment relative to the front side. Since a MA basically uses only two alignment marks, a MA may be equipped with a BSAS, which may detect, during back side exposure, marks on the wafer front side (in this case the side facing the chuck) through openings in the chuck. This may, for example, be provided for highly-doped wafers or wafers covered with a metal layer (e.g. a seed layer for electroplating) where back side alignment through the wafer with IR (infrared) light from above may no longer be possible. If the wafer, though, possesses an extremely high topography at some locations (for example, a reinforced edge stabilization ring), a correspondingly high proximity gap may need to be kept between mask and wafer, which in turn may drastically deteriorate the resolution of the MA exposure, so that the advantage of BSAS may not be exploited in such cases due to insufficient resolution.

Wafers without high topography (e.g. without reinforcement ring) may be readily aligned (for example, using infrared (IR) light or near-IR light) and exposed using a mask aligner. Up to now, though, it has been difficult or not possible at all to produce supported thin wafers having a high or extremely high topography (e.g. wafers having a reinforcement ring) on a mask aligner with acceptable resolution.

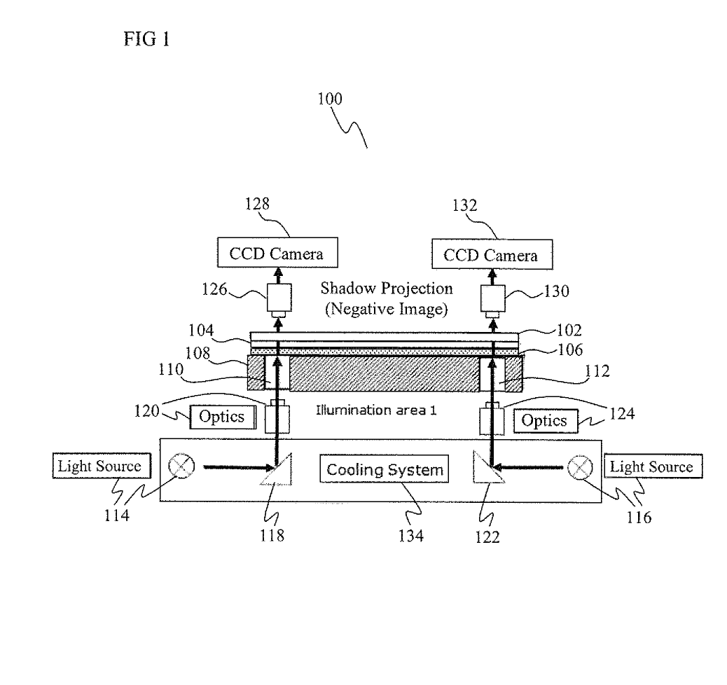

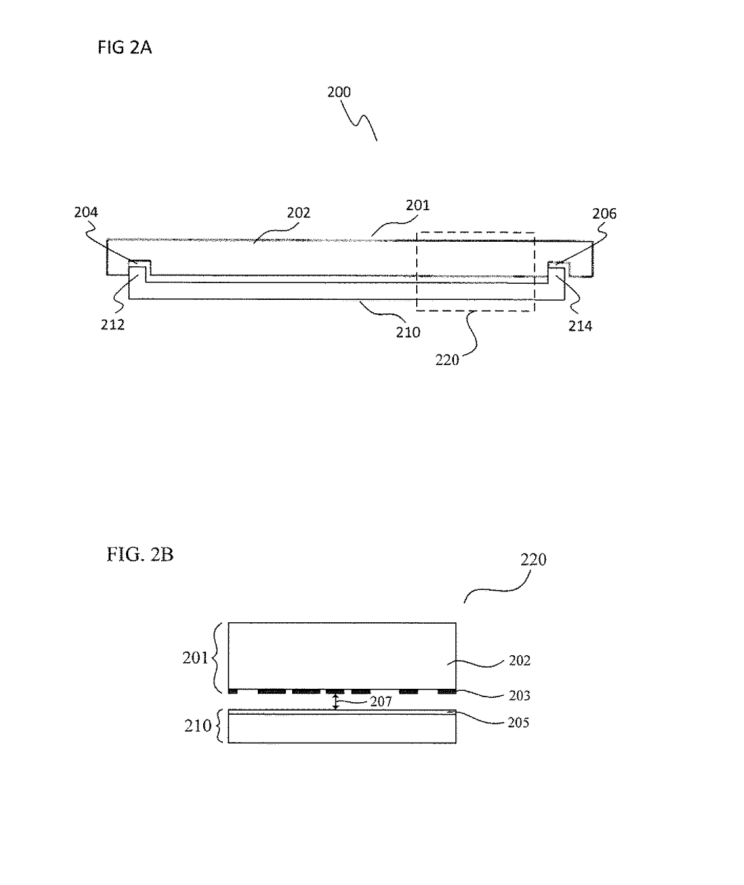

FIG. 1 shows an exemplary mask aligner arrangement 100. The mask aligner arrangement 100 may include a photolithography mask 102 having at least substantially flat surfaces, and a wafer 104 having at least substantially flat surfaces (for example without a reinforcement ring), to be exposed using the photolithography mask 102. The photolithography mask 102 may, for example, include a transparent substrate (e.g. a glass substrate), wherein parts of the transparent substrate may be coated with a light-absorbing layer (e.g. a chrome layer) that may absorb light (not shown, see e.g. FIG. 2B). The thickness of the wafer 104 may be in the range from about 25 μm to about 250 μm, e.g. in the range from about 30 μm to about 150 μm, e.g. in the range from about 35 μm to about 130 μm, e.g. in the range from about 50 μm to about 100 μm, e.g. in the range from about 60 μm to about 80 μm, e.g. about 70 um. As the photolithography mask 102 and the wafer 104 have at least substantially flat surfaces, the photolithography mask 102 and the wafer 104 may be arranged with a small proximity gap, relative to each other.

The photolithography mask 102 and the wafer 104 may be arranged over a carrier (e.g. a glass carrier) 106 of a thickness of about 400 μm and positioned over a chuck 108, for example, for exposure of the wafer 104 using the photolithography mask 102. The chuck 108 may be a part of a mask aligner.

The chuck 108 may include one or more openings, for example a first opening 110 and a second opening 112, which may allow respective light from respective light sources (e.g. infra-red (IR) light sources) 114, 116, to be directed through the first opening 110 and the second opening 112 respectively to enable relative alignment of the photolithography mask 102 and the wafer 104.

The light from the light source 114 may be at least partially reflected by a reflecting element (e.g. a beamsplitter or a mirror) 118, and coupled to an arrangement of optics 120, which may include, for example, a filter and/or a lens, to be passed through the first opening 110 of the chuck 108. Similarly, the light from the light source 116 may be at least partially reflected by a reflecting element (e.g. a beamsplitter or a mirror) 122, and coupled to an arrangement of optics 124, which may include, for example, a filter and/or a lens, to be passed through the second opening 112 of the chuck 108.

The light passing through the first opening 110 of the chuck 108 may at least partially pass through the photolithography mask 102, the wafer 104 and the carrier 106, to an arrangement of optics 126 which may include, for example, a filter and/or a lens, and collected by a first imaging device (e.g. a camera, e.g. a CCD camera, although any other camera may be used if desired) 128 to form an image. Similarly, the light passing through the second opening 112 of the chuck 108 may at least partially pass through the photolithography mask 102, the wafer 104 and the carrier 106, to an arrangement of optics 130 which may include, for example, a filter and/or a lens, and collected by a second imaging device (e.g. a camera, e.g. a CCD camera, although any other camera may be used if desired) 132 to form another image. The images collected by the imaging devices 128, 132, may be used to guide and ensure proper alignment of the photolithography mask 102 relative to the wafer 104.

A cooling system (e.g. a fan and/or cooling structures such as e.g. cooling ribs) 134 may be provided, for example, to cool the light sources 114, 116, and/or any other optical components (e.g. 118, 120, 122, 124).

It may be understood that the configuration of the mask aligner arrangement 100 illustrated in FIG. 1 is only exemplary and various modifications or changes may be made with respect to the presence or arrangement of individual components (e.g. light sources, optics, imaging devices, cooling system, etc.) in a mask aligner arrangement in general. For example, one or more of the components of the mask aligner arrangement 100 shown in FIG. 1 may be arranged or configured differently, or may be replaced by one or more other components, or may be omitted, or one or more additional components may be present, in other mask aligner arrangements.

For example, in contrast to the configuration illustrated in FIG. 1 where IR light coming from below the chuck 108 passes through the openings 110, 112, the carrier 106, the wafer 104 and the photolithography mask 102 into front side imaging devices 128, 132, in another configuration (not shown) it may be possible that near-IR light coming from below the chuck 108 passes through the openings 110, 112 and the carrier 106, is at least partially reflected by a front side pattern of the wafer 104 and then goes down again to a back side imaging device.

Up to now, exposure of wafers with insufficient IR transparency and extreme topography cannot be achieved easily. For a large proximity gap it may be possible to create large alignment marks on the wafer back side by means of exposure with a mask aligner. These alignment marks may subsequently be used by a so-called “stepper” (a projection exposure tool where the front lens is located far away from the wafer so that the topography of the wafer plays no role), in order to generate the fine structures. However, the relatively coarse auxiliary structures used for alignment are generally only poorly defined due to the process how they were created, so that only a moderate overlay accuracy may be achieved. Presently, there is no equipment or tools (or they are too expensive) having imaging optics when using a mask for a whole wafer.

When using a mask aligner (e.g. the mask aligner shown in FIG. 1), the table of the mask aligner for holding a wafer (e.g. wafer 104 shown in FIG. 1) may have openings (e.g. openings 110, 112 shown in FIG. 1) that may allow light to pass through. The mask (e.g. mask 102 shown in FIG. 1) may be moved to enable alignment with the wafer. The mask needs to be close to the wafer (low proximity gap, e.g. in the range from about 5 μm to about 100 μm, e.g. in the range from about 7 μm to about 70 μm, e.g. in the range from about 8 μm to about 60 μm, e.g. in the range from about 10 μm to about 50 μm) during exposure in order to increase resolution. During alignment, the mask may be arranged farther away from the wafer (e.g. 0.5 mm to 1 mm) as microscopes with a higher focal length may be employed for alignment purposes.

FIG. 2A shows a photolithography mask arrangement 200 according to various embodiments, from a side view, and FIG. 2B shows an enlarged view of a section 220 of the photolithography mask arrangement 200. The photolithography mask arrangement 200 may include a photolithography mask 201 and a wafer 210. The photolithography mask 201 may include a mask substrate 202 having a three-dimensional pattern (e.g. a three-dimensional shape) located and dimensioned to at least partially receive an inverse three-dimensional pattern (e.g. a three-dimensional shape) of the wafer 210 to be exposed using the photolithography mask 201. The mask substrate 202 may include or be made of a transparent material. The photolithography mask 201 may further include a light-absorbing layer 203 that may be coated on one or more portions of a surface of the mask substrate 202 facing the wafer 210, as shown in FIG. 2B. The light-absorbing layer 203 may, for example, include or be made of a light-absorbing material such as, for example, chrome or the like. The wafer 210 may include a photosensitive layer 205 (e.g. a resist layer) disposed at a surface (e.g. back side) of the wafer 210 facing the photolithography mask 201, as shown in FIG. 2B. The light-absorbing layer 203 may define a pattern to be transferred to the photosensitive layer 205 during exposure. FIG. 2B further shows a distance 207 between the photolithography mask 201 and the wafer 210, more precisely between the light-absorbing layer 203 of the photolithography mask 201 and the photosensitive layer 205 of the wafer according to this embodiment. The distance 207 may correspond to a minimal distance between the photolithography mask 201 and the wafer 210 and may also be referred to as the proximity gap between the wafer 210 and the photolithography mask 201.

The mask 201 may include one or more recesses (e.g. one or more grooves), for example a first groove 204 and a second groove 206. The first groove 204 and the second groove 206 may be located and dimensioned to at least partially receive respective protrusions, for example a first protrusion 212 and a second protrusion 214, of an inverse three-dimensional pattern of the wafer 210. For example, the mask substrate 202 and the wafer 210 may be arranged such that the first groove 204 corresponds to the first protrusion 212 and the second groove 206 corresponds to the second protrusion 214. In other words, the first protrusion 212 may be (at least partially) received or accommodated by (or in) the first groove 204 and the second protrusion 214 may be (at least partially) received or accommodated by (or in) the second groove 206. The one or more recesses (e.g. one or more grooves), for example the first groove 204 and the second groove 206 may, for example, be formed mechanically (e.g. milling) or by exposure (or patterning) and etching.

Each of the first groove 204 and the second groove 206 may have a width of about at least 100 μm (≧0.1 mm), for example a width in a range from about 0.1 mm to about 100 mm, for example a range from about 0.1 mm to about 40 mm, for example a range from about 0.1 mm to about 20 mm, for example a range from about 1 mm to about 10 mm, for example a width of about 6 mm in accordance with various embodiments. Other values may be possible as well in accordance with other embodiments.

Each of the first groove 204 and the second groove 206 may have a depth in the range from about 50 μm to about 1000 μm, e.g. a depth in the range from about 150 μm to about 500 μm, for example a depth of about 300 μm in accordance with various embodiments. Other values may be possible as well in accordance with other embodiments.

The wafer 210 may be a thin wafer. The thickness of the wafer 210 may be for example in the range from about 50 μm and about 150 μm, e.g. in the range from about 70 μm to about 120 μm. The thickness of each of the first protrusion 212 and the second protrusion 214, including the thickness of the wafer 210, may be in the range from about 30 μm to about 800 μm, e.g. in the range from about 100 μm to about 400 μm, e.g. about 400 μm.

In various embodiments, the first groove 204 and the second groove 206 may be continuous and may have a ring shape. In other words, the first groove 204 and the second groove 206 may form a ring-shaped groove located in the mask substrate 202. In various embodiments, the first protrusion 212 and the second protrusion 214 may be continuous and may be a reinforcement ring. Therefore, the first groove 204 and the second groove 206 in the form of a ring-shaped groove may receive (at least partially), for example, a reinforcement ring of the wafer 210.

The mask substrate 202 may include or may be made of a transparent material such as, for example, quartz glass, calcium fluoride, or other suitable transparent materials.

By providing one or more recesses (e.g. one or more grooves), for example the first groove 204 and the second groove 206, on the mask substrate 202, the proximity gap between the mask 201 and the wafer 210 having a high topography at some locations (e.g. the first protrusion 212 and the second protrusion 214, for example, a reinforced edge stabilization ring), may be reduced, as the high topographies may be (at least partially) received or accommodated by (or in) the first groove 204 and the second groove 206. Therefore, the three-dimensional pattern of the mask substrate 202 may be complementary to the inverse three-dimensional pattern of the wafer 210.

It may be understood that, although not shown in FIG. 2A, the first and second protrusions 212, 214 (or a plurality of protrusions in general) may have different heights in accordance with some embodiments, for example in one or more embodiments where the protrusions may be physically separated from one another or discontiguous. That is, the first protrusion 212 may have a height that is different from a height of the second protrusion 214. Correspondingly, the first groove 204 (that may be configured to receive at least partially the first protrusion 212) may have a depth that is different from a depth of the second groove 206 (that may be configured to receive at least partially the second protrusion 214).

In accordance with some embodiments, a photolithography mask (herein also referred to as photomask or, short, mask) having a groove located in the mask (for example, in a mask substrate of the mask) is provided. By means of the groove, the proximity gap between the mask (e.g. between an active part of the mask with respect to a pattern to be printed) and a wafer having a reinforcement ring may be reduced to a degree that allows for a clear (in other words, high) definition of the structures. The reinforcement ring may be (at least partially) received or accommodated by (or in) the groove, see e.g. FIG. 2A.

In accordance with various embodiments, a three-dimensionally structured photomask (mask) may be provided, which may, for example, be used for exposure of a wafer or wafers having extreme singular topography on a mask aligner, in order to achieve a good resolution. The structures on the mask may, for example, include or be one or more recesses (e.g. grooves), which may at least partially receive or accommodate structures protruding from the wafer surface and may thus allow for a low proximity gap between the mask and the wafer.

In accordance with various embodiments, one or more recesses may be formed in a photomask (for example, in a mask substrate of the mask) at locations, which correspond to locations of a wafer where the wafer has a protrusion or protrusions. The recesses may, for example, be formed at locations of the wafer where the structures of the wafer topography protrude particularly high. Thus, it may be possible to bring the mask sufficiently close to the wafer (small proximity gap) so that a good resolution may be achieved and, for example, a mask aligner may be used again for back side alignment. Thus, wafers having low IR transparency and high singular topography may be exposed on the back side, with good precision and alignment with respect to the front side, in a single processing step without having to create auxiliary alignment marks first.

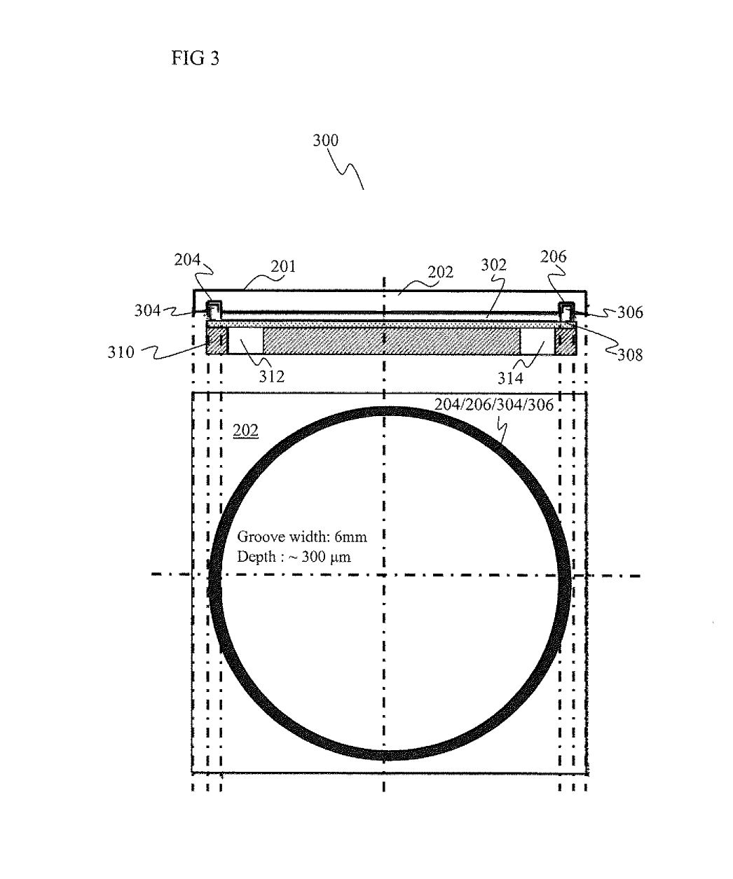

In accordance with some embodiments, a photomask having a groove may be provided. By means of the groove in the mask, the proximity gap between the mask and a wafer may be reduced to a degree, which enables a clear (in other words, high) resolution of structures. A reinforcement ring of the wafer may be at least partially be received in the groove, as shown e.g. in FIG. 3.

FIG. 3 shows a photolithography mask arrangement 300 according to various embodiments. The photolithography mask arrangement 300 may include a photolithography mask 201 including a mask substrate 202, and a wafer 302, where the mask substrate 202 has a three-dimensional pattern (e.g. a three-dimensional shape) located and dimensioned to at least partially receive an inverse three-dimensional pattern of the wafer 302 to be exposed using the photolithography mask 201, and the mask 302 having the inverse three-dimensional pattern. The thickness of the wafer 302 may be about 120 μm. The wafer 302 may be a thin wafer.

The mask substrate 202 may include at least one recess (e.g. groove), for example a first groove 204 and a second groove 206, which may be as described in the context of the embodiment of FIG. 2A. Each of the first groove 204 and the second groove 206 may have a width in the range from about 0.1 mm to about 100 mm, e.g. a width in the range from about 1 mm to about 10 mm, e.g. a width of about 6 mm. Furthermore, each of the first groove 204 and the second groove 206 may have a depth in the range from about 50 μm mm to about 1000 μm, e.g. a depth in the range from about 150 μm mm to about 500 μm mm, e.g. a depth of about 300 μm.

The inverse three-dimensional pattern of the wafer 302 may include at least one protrusion, for example a first protrusion 304 and a second protrusion 306, or a plurality of protrusions (i.e., an arbitrary number greater than or equal to two). The mask substrate 202 and the wafer 304 may be arranged such that the first groove 204 corresponds to the first protrusion 304 and the second groove 206 corresponds to the second protrusion 306. In other words, the first protrusion 304 may be (at least partially) received or accommodated by (or in) the first groove 204 and the second protrusion 306 may be (at least partially) received or accommodated by (or in) the second groove 206. The thickness of each of the first protrusion 304 and the second protrusion 306, including the thickness of the wafer 302, may be about 400 μm.

As illustrated in FIG. 3, the first groove 204 and the second groove 206 may form a ring-shaped groove and the first protrusion 304 and the second protrusion 306 may be or may include a reinforcement ring of the wafer 302, corresponding to the ring-shaped groove.

The photolithography mask 201 and the wafer 302 may be arranged over a carrier (e.g. a glass carrier) 308 and positioned over a chuck 310, for example, for exposure of the wafer 302 using the photolithography mask 201. The carrier 308 may be used for reinforcement and may be optionally provided for a thin wafer and may not be required for a thick wafer. The chuck 310 may be a part of a mask aligner (not shown). The chuck 310 may include one or more openings, for example a first opening 312 and a second opening 314, which may allow respective lights to be directed through the first opening 312 and the second opening 314 to enable relative alignment of the photolithography mask 200 and the wafer 302.

Exposure of the wafer 302 by the photolithography mask 201 may be performed using a mask aligner arrangement, for example mask aligner arrangement 100 as described in the context of FIG. 1, or the like. A negative imprint or pattern (corresponding to the topography of the wafer 302) in the mask 201, e.g. recess or groove corresponding to reinforcement ring of a (thin) wafer, may be provided. By providing one or more recesses (e.g. one or more grooves), for example the first groove 204 and the second groove 206, on the mask substrate 202, the proximity gap between the mask 201 and a wafer (e.g. 302) having a high topography at some locations (for example, a reinforced edge stabilization ring), may be reduced, as the high topographies may be (at least partially) received or accommodated by (or in) the first groove 204 and the second groove 206. For example, with proximity exposure use of mask aligner (MA), a proximity gap in the range from about 10 μm to about 20 μm may be provided, achieving resolutions down to approximately 2 μm, for example. In addition, with contact exposure (e.g. mask 201 in direct contact with the wafer 302), resolutions down to approximately 1 μm may be achieved. However, the mask 201 may be damaged due to the contact with the wafer 302.

In accordance with some embodiments, photolithographical processing of devices, which may require a back side implantation (aligned or not aligned relative to the front side), such as, for example, IGBT (insulated gate bipolar transistor) devices or EMCON (emitter controlled) diodes, may be achieved with improved or high resolution. This may be due to the use of a photolithography mask having one or more recesses (e.g. one or more grooves) that may allow for reducing a proximity gap between wafer and mask as singular topographical elements of the wafer such as, for example, a reinforcement ring, may be at least partially received by the one or more recesses (e.g. one or more grooves) of the mask.

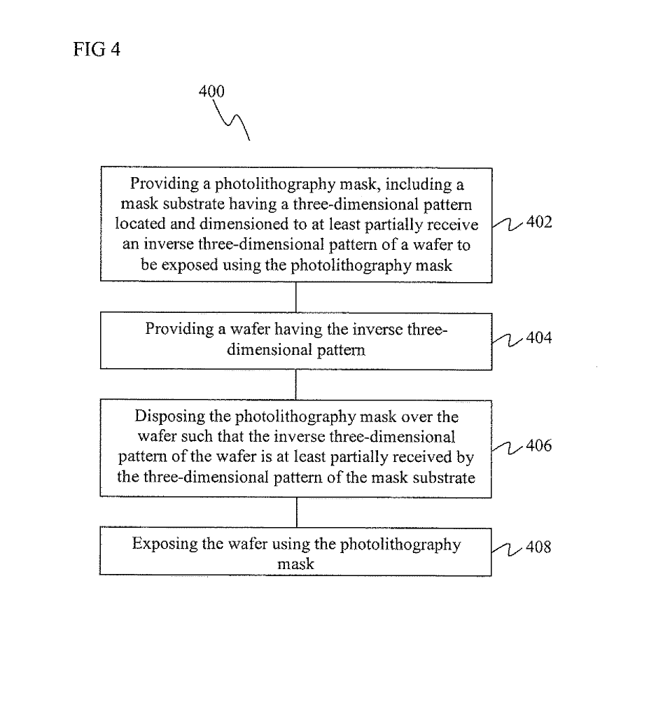

FIG. 4 shows a method 400 for exposing a wafer according to another embodiment.

At 402, a photolithography mask is provided, the photolithography mask including a mask substrate having a three-dimensional pattern located and dimensioned to at least partially receive an inverse three-dimensional pattern of a wafer to be exposed using the photolithography mask.

At 404, a wafer having the inverse three-dimensional pattern is provided.

At 406, the photolithography mask is disposed over the wafer such that the inverse three-dimensional pattern of the wafer is at least partially received by the three-dimensional pattern of the mask substrate.

At 408, the wafer is exposed using the photolithography mask.

A photolithography mask in accordance with various embodiments may include: a mask substrate, the mask substrate having a three-dimensional pattern located and dimensioned to at least partially receive an inverse three-dimensional pattern of a wafer to be exposed using the photolithography mask.

In accordance with an embodiment, the three-dimensional pattern of the mask substrate may include at least one recess located and dimensioned to at least partially receive at least one protrusion of the inverse three-dimensional pattern of the wafer.

In accordance with another embodiment, the at least one recess may have a width in the range from about 0.1 mm to about 100 mm, for example a width of about 6 mm in accordance with another embodiment. Other values may be possible as well in accordance with other embodiments.

In accordance with another embodiment, the at least one recess may have a depth in the range from about 50 μm to about 1000 μm, for example a depth of about 300 lam in accordance with another embodiment. Other values may be possible as well in accordance with other embodiments.

In accordance with another embodiment, the at least one recess may have a ring shape corresponding to a reinforcement ring of the wafer. For example, the at least one recess may include or be a ring-shaped groove.

In accordance with another embodiment, the mask substrate may include or may be made of a transparent material such as, for example, quartz glass, calcium fluoride, or other suitable transparent materials.

A photolithography mask in accordance with various embodiments may include: a mask substrate; and a ring-shaped groove located in the mask substrate and dimensioned to at least partially receive a reinforcement ring of a wafer to be exposed using the photolithography mask.

In accordance with an embodiment, the groove may have a width in the range from about 0.1 mm to about 100 mm, for example a width of about 6 mm in accordance with another embodiment. Other values may be possible as well in accordance with other embodiments.

In accordance with another embodiment, the groove may have a depth in the range from about 50 μm to about 1000 μm, for example a depth of about 300 μm in accordance with another embodiment. Other values may be possible as well in accordance with other embodiments.

In accordance with another embodiment, the mask substrate may include or may be made of a transparent material such as, for example, quartz glass, calcium fluoride, or other suitable transparent materials.

A photolithography mask arrangement in accordance with various embodiments may include: a photolithography mask including a mask substrate, the mask substrate having a three-dimensional pattern located and dimensioned to at least partially receive an inverse three-dimensional pattern of a wafer to be exposed using the photolithography mask; and a wafer having the inverse three-dimensional pattern.

In accordance with an embodiment, the three-dimensional pattern of the mask substrate may include at least one recess located and dimensioned to at least partially receive at least one protrusion of the inverse three-dimensional pattern of the wafer; and the inverse three-dimensional pattern of the wafer may include at least one protrusion corresponding to the at least one recess.

In accordance with another embodiment, the at least one recess may have a width in the range from about 0.1 mm to about 20 mm, for example a width of about 6 mm in accordance with another embodiment. Other values may be possible as well in accordance with other embodiments.

In accordance with another embodiment, the at least one recess may have a depth in the range from about 50 μm to about 1000 μm, for example a depth of about 300 μm in accordance with another embodiment. Other values may be possible as well in accordance with other embodiments.

In accordance with another embodiment, the at least one protrusion may include or may correspond to a reinforcement ring of the wafer; and the at least one recess may have a ring shape corresponding to the reinforcement ring.

In accordance with another embodiment, the mask substrate may include or may be made of a transparent material such as, for example, quartz glass, calcium fluoride, or other suitable transparent materials.

A method for exposing a wafer in accordance with various embodiments may include: providing a photolithography mask including a mask substrate, the mask substrate having a three-dimensional pattern located and dimensioned to at least partially receive an inverse three-dimensional pattern of a wafer to be exposed using the photolithography mask; providing a wafer having the inverse three-dimensional pattern; disposing the photolithography mask over the wafer such that the inverse three-dimensional pattern of the wafer is at least partially received by the three-dimensional pattern of the mask substrate; exposing the wafer using the photolithography mask.

In accordance with an embodiment, disposing the photolithography mask over the wafer may include disposing the photolithography mask such that a proximity gap between the photolithography mask and the wafer is equal to or less than about 50 μm, for example in the range from about 10 μm to about 50 μm in accordance with another embodiment. Other values may be possible as well in accordance with other embodiments.

In accordance with another embodiment, the three-dimensional pattern of the mask substrate may include at least one recess located and dimensioned to at least partially receive at least one protrusion of the inverse three-dimensional pattern of the wafer; and the inverse three-dimensional pattern of the wafer may include at least one protrusion corresponding to the at least one recess.

In accordance with another embodiment, the at least one recess may have a width in the range from about 0.1 mm to about 20 mm, for example a width of about 6 mm in accordance with another embodiment. Other values may be possible as well in accordance with other embodiments.

In accordance with another embodiment, the at least one recess may have a depth in the range from about 50 μm to about 1000 μm, for example a depth of about 300 μm in accordance with another embodiment. Other values may be possible as well in accordance with other embodiments.

In accordance with another embodiment, the at least one protrusion may include or may be a reinforcement ring of the wafer; and the at least one recess may have a ring shape corresponding to the reinforcement ring.

In accordance with another embodiment, the mask substrate may include or may be made of a transparent material such as, for example, quartz glass, calcium fluoride, or other suitable transparent materials.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A photolithography mask, comprising:
a mask substrate;
the mask substrate having a three-dimensional pattern located and dimensioned to at least partially receive an inverse three-dimensional pattern of a wafer to be exposed using the photolithography mask.

2. The photolithography mask of claim 1,
wherein the three-dimensional pattern of the mask substrate comprises at least one recess located and dimensioned to at least partially receive at least one protrusion of the inverse three-dimensional pattern of the wafer.

3. The photolithography mask of claim 2,
wherein the at least one recess has a width in the range from about 0.1 mm to about 100 mm.

4. The photolithography mask of claim 2,
wherein the at least one recess has a depth in the range from about 50 μm to about 1000 μm.

5. The photolithography mask of claim 2,
wherein the at least one recess has a ring shape corresponding to a reinforcement ring of the wafer.

6. The photolithography mask of claim 1,
wherein the mask substrate comprises a transparent material.

7. The photolithography mask of claim 6,
wherein the transparent material comprises at least one of quartz glass and calcium fluoride.

8. A photolithography mask, comprising:
a mask substrate;
a ring-shaped groove located in the mask substrate and dimensioned to at least partially receive a reinforcement ring of a wafer to be exposed using the photolithography mask.

9. The photolithography mask of claim 8,
wherein the groove has a width in the range from about 0.1 mm to about 100 mm.

10. The photolithography mask of claim 8,
wherein the groove has a depth in the range from about 50 μm to about 1000 μm.

11. The photolithography mask of claim 8,
wherein the mask substrate comprises a transparent material.

12. The photolithography mask of claim 11,
wherein the transparent material comprises at least one of quartz glass and calcium fluoride.

13. A photolithography mask arrangement, comprising:
a photolithography mask, comprising:
a mask substrate;
the mask substrate having a three-dimensional pattern located and dimensioned to at least partially receive an inverse three-dimensional pattern of a wafer to be exposed using the photolithography mask;
a wafer having the inverse three-dimensional pattern.

14. The photolithography mask arrangement of claim 13,
wherein the three-dimensional pattern of the mask substrate comprises at least one recess located and dimensioned to at least partially receive at least one protrusion of the inverse three-dimensional pattern of the wafer;
wherein the inverse three-dimensional pattern of the wafer comprises at least one protrusion corresponding to the at least one recess.

15. The photolithography mask arrangement of claim 14,
wherein the at least one recess has a width in the range from about 0.1 mm to about 100 mm.

16. The photolithography mask arrangement of claim 14,
wherein the at least one recess has a depth in the range from about 50 μm to about 1000 μm.

17. The photolithography mask arrangement of claim 14,
wherein the at least one protrusion comprises a reinforcement ring of the wafer; and
wherein the at least one recess has a ring shape corresponding to the reinforcement ring.

18. The photolithography mask arrangement of claim 13,
wherein the mask substrate comprises a transparent material.

19. The photolithography mask arrangement of claim 18,
wherein the transparent material comprises at least one of quartz glass and calcium fluoride.

20. A method for exposing a wafer, the method comprising:
providing a photolithography mask, comprising a mask substrate having a three-dimensional pattern located and dimensioned to at least partially receive an inverse three-dimensional pattern of a wafer to be exposed using the photolithography mask;
providing a wafer having the inverse three-dimensional pattern;
disposing the photolithography mask over the wafer such that the inverse three-dimensional pattern of the wafer is at least partially received by the three-dimensional pattern of the mask substrate;
exposing the wafer using the photolithography mask.

21. The method of claim 20,
wherein disposing the photolithography mask over the wafer comprises disposing the photolithography mask such that a proximity gap between the photolithography mask and the wafer is equal to or less than about 50 μm.

22. The method of claim 20,
wherein the three-dimensional pattern of the mask substrate comprises at least one recess located and dimensioned to at least partially receive at least one protrusion of the inverse three-dimensional pattern of the wafer;
wherein the inverse three-dimensional pattern of the wafer comprises at least one protrusion corresponding to the at least one recess.

23. The method of claim 22,
wherein the at least one recess has a width in the range from about 0.1 mm to about 100 mm.

24. The method of claim 22,
wherein the at least one recess has a depth in the range from about 50 μm to about 1000 μm.

25. The method of claim 22,
wherein the at least one protrusion comprises a reinforcement ring of the wafer;
and
wherein the at least one recess has a ring shape corresponding to the reinforcement ring.

26. The method of claim 20,
wherein the mask substrate comprises a transparent material.

27. The method of claim 26,
wherein the transparent material comprises at least one of quartz glass and calcium fluoride.
